(19) United States
(12) Patent Application Publication
(10) Pub. No.: US 2011/0181353 A1
(43) Pub. Date: Jul. 28, 2011

(54) TWO-CHANNEL OPERATIONAL AMPLIFIER CIRCUIT

(75) Inventors: Ju-Lin HUANG, Hsinchu County (TW); Chia-Wei Su, Hsinchu City (TW); Po-Yu Tseng, Taoyuan County (TW)

(73) Assignee: NOVATEK MICROELECTRONICS CORP., HsinChu (TW)

(21) Appl. No.: 12/797,338

(22) Filed: Jun. 9, 2010

(30) Foreign Application Priority Data
Jan. 28, 2010 (TW) 99102485

(51) Int. Cl. H03F 3/68

(52) U.S. Cl. 330/124 R; 330/295

(57) ABSTRACT

A two-channel operational amplifier circuit includes a first operational amplifier and a second operational amplifier. In a first frame period, the two-channel operational amplifier circuit switches a first input stage, a first gain stage and a first output stage to work between a working voltage and a half working voltage, and switches a second input stage, a second gain stage and a second output stage to work between the half working voltage and a ground voltage. In a second frame period, the two-channel operational amplifier circuit switches the second input stage and the second gain stage to work between the working voltage and the half working voltage, and switches the first input stage and the first gain stage to work between the half working voltage and the ground voltage.

This application claims the benefit of Taiwan application Serial No. 99102485, filed Jan. 28, 2010, the subject matter of which is incorporated herein by reference.

### BACKGROUND OF THE INVENTION

1. Field of the Invention

The invention relates in general to a two-channel operational amplifier circuit, and more particularly to a two-channel operational amplifier circuit, which is low power-consumptive and can avoid the abnormal display.

2. Description of the Related Art

Operational amplifiers in conventional source drivers may be classified as operating in a half-VDD operation mode or a full-VDD operation mode. FIG. 1 (Prior Art) is a schematic illustration showing a conventional operational amplifier circuit 100 operating in a half-VDD operation mode. According to the requirement of the polarity conversion of the liquid crystal display, the operational amplifier circuit 100 needs to output different polarities of data to the nodes N1 and N2 in different frame periods. In one first frame period FP1, the positive polarity data PS is outputted to the node N1 through a first input stage 112, a first gain stage 114 and a first output stage 116, and the negative polarity data NS is outputted to the node N2 through a second input stage 122, a second gain stage 124 and a second output stage 126.

In a second frame period FP2, the positive polarity data PS is outputted to the node N2 through the first input stage 112, the first gain stage 114 and the first output stage 116, and the negative polarity data NS is outputted to the node N1 through the second input stage 122, the second gain stage 124 and the second output stage 126. For the single node, however, the positive polarity data and the negative polarity data are respectively processed by different input stages and different gain stages so that different voltage offsets are caused. Consequently, errors may be generated during the polarity conversion so that the liquid crystal display generates the flicker phenomenon, and an extra compensation mechanism is required to solve this problem.

FIG. 2 (Prior Art) is a schematic illustration showing a conventional operational amplifier circuit 200 operating in a full-VDD operation mode. According to the requirement of the polarity conversion of the liquid crystal display, the operational amplifier circuit 200 needs to output different polarities of data to the nodes N1 and N2 in different frame periods. In the first frame period FP1, the positive polarity data PS is outputted to the node N1 through a first input stage 212, a first gain stage 214 and a first output stage 216, and the negative polarity data NS is outputted to the node N2 through a second input stage 222, a second gain stage 224 and a second output stage 226.

In the second frame period FP2, the positive polarity data PS is outputted to the node N2 through the second input stage 222, the second gain stage 224 and the first output stage 216, and the negative polarity data NS is outputted to the node N1 through the first input stage 212, the first gain stage 214 and the second output stage 226. Consequently, the positive polarity data and the negative polarity data for the single node are respectively processed by the same input stage and the same gain stage, so the problem of voltage offset cannot be caused. However, because the full-VDD operation is adopted, the first input stage 212 and the second input stage 222 cannot share currents and the first gain stage 214 and the second gain stage 224 cannot share currents so that the current consumption is higher.

### SUMMARY OF THE INVENTION

The invention is directed to a two-channel operational amplifier circuit, wherein different polarities of data of one single output node are processed by the same input stage and the same gain stage so that the problem of the abnormal display can be avoided. In addition, switches are switched so that the two-channel operational amplifier circuit operates in a half-VDD operation mode to save the current consumption.

According to the present invention, a two-channel operational amplifier circuit including a first operational amplifier and a second operational amplifier is provided. The first operational amplifier has a first input stage, a first gain stage and a first output stage. The second operational amplifier has a second input stage, a second gain stage and a second output stage. The second operational amplifier and the first operational amplifier operate in a half-VDD operation mode. In a first frame period, the two-channel operational amplifier circuit switches the first input stage, the first gain stage and the first output stage to work between a working voltage and a half working voltage, such that a positive polarity signal is outputted to a first node through the first input stage, the first gain stage and the first output stage, and the two-channel operational amplifier circuit switches the second input stage, the second gain stage and the second output stage to work between the half working voltage and a ground voltage, such that a negative polarity signal is outputted to a second node through the second input stage, the second gain stage and the second output stage. In a second frame period, the two-channel operational amplifier circuit switches the second input stage, the second gain stage and the first output stage to work between the working voltage and the half working voltage, such that the positive polarity signal is outputted to the second node through the second input stage, the second gain stage and the first output stage, and the two-channel operational amplifier circuit switches the first input stage, the first gain stage and the second output stage to work between the half working voltage and the ground voltage, such that the negative polarity signal is outputted to the first node through the first input stage, the first gain stage and the second output stage.

The invention will become apparent from the following detailed description of the preferred but non-limiting embodiments. The following description is made with reference to the accompanying drawings.

### BRIEF DESCRIPTION OF THE DRAWINGS

FIG. 1 (Prior Art) is a schematic illustration showing a conventional operational amplifier circuit operating in a half-VDD operation mode.

FIG. 2 (Prior Art) is a schematic illustration showing a conventional operational amplifier circuit operating in a full-VDD operation mode.

FIG. 3 is a schematic illustration showing a two-channel operational amplifier circuit according to a preferred embodiment of the invention.

FIGS. 4A and 4B are circuit diagrams showing the two-channel operational amplifier circuit according to the preferred embodiment of the invention.

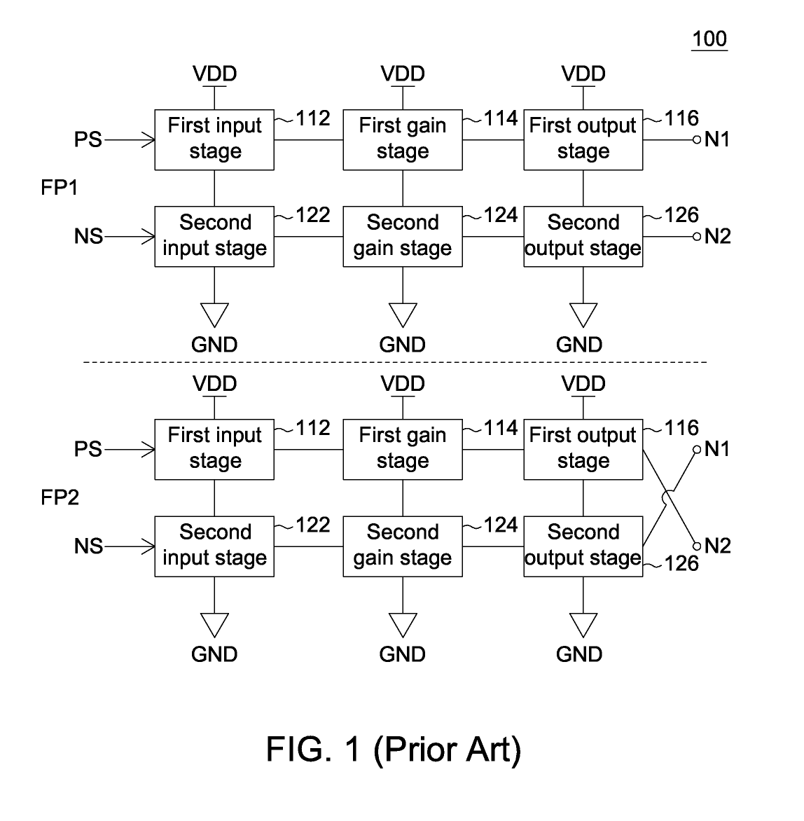

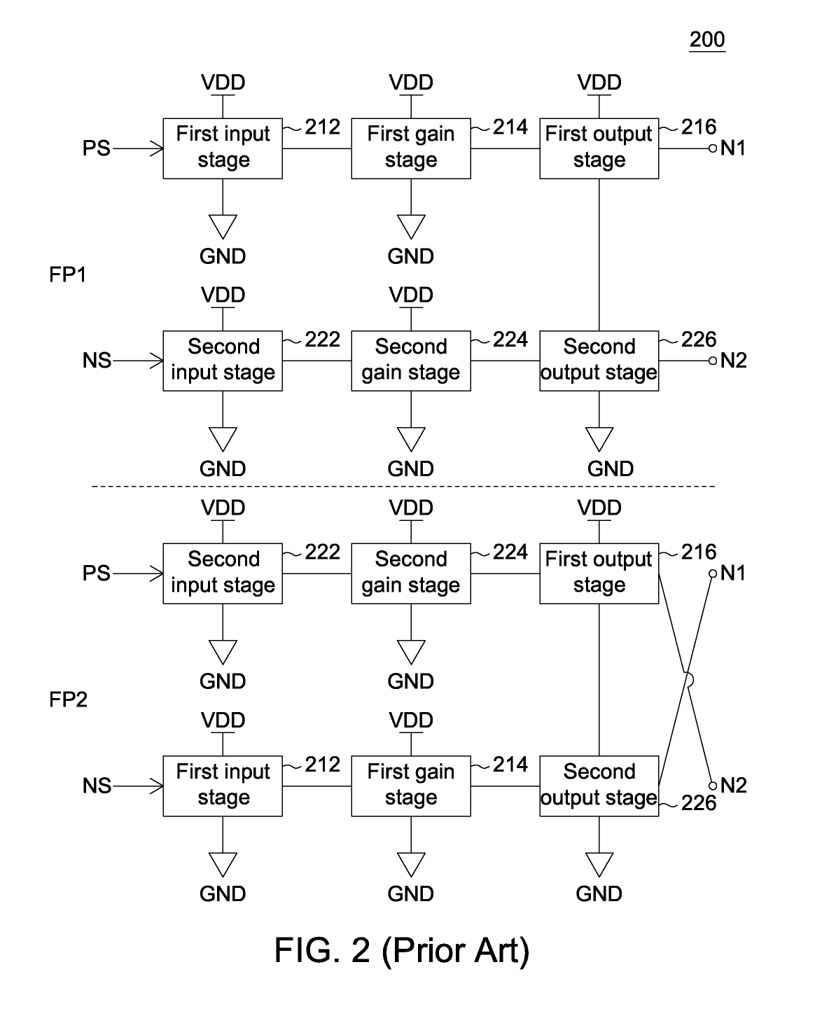

### DETAILED DESCRIPTION OF THE INVENTION

The invention proposes a two-channel operational amplifier circuit, wherein different polarities of data of one single output node are processed by the same input stage and the same gain stage so that the problem of the abnormal display can be avoided. In addition, switches are switched so that the two-channel operational amplifier circuit operates in a half-VDD operation mode to save the current consumption.

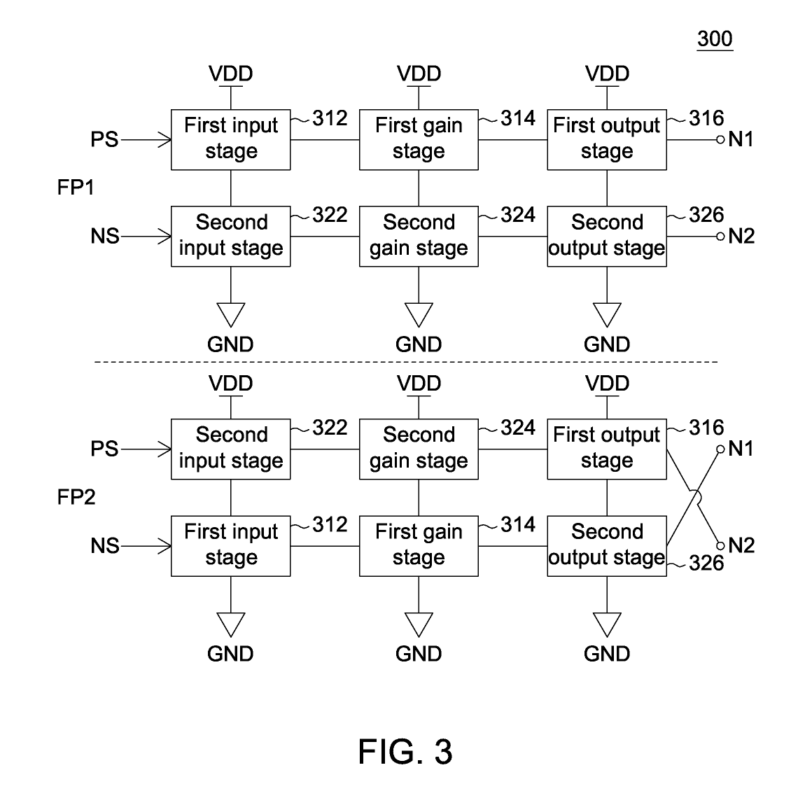

FIG. 3 is a schematic illustration showing a two-channel operational amplifier circuit 300 according to a preferred embodiment of the invention. Referring to FIG. 3, the two-channel operational amplifier circuit 300 includes a first operational amplifier and a second operational amplifier. The first operational amplifier has a first input stage 312, a first gain stage 314 and a first output stage 316. The second operational amplifier has a second input stage 322, a second gain stage 324 and a second output stage 326. The two-channel operational amplifier circuit 300 makes the second operational amplifier and the first operational amplifier operate in a half-VDD operation mode.

The two-channel operational amplifier circuit 300 may be applied to a source driver of a liquid crystal display. According to the requirement on the polarity conversion of the liquid crystal display, the operational amplifier circuit 300 needs to output different polarities of data to nodes N1 and N2 in different frame periods.

In a first frame period FP1, the two-channel operational amplifier circuit 300 switches the first input stage 312, the first gain stage 314 and the first output stage 316 to work between a working voltage VDD and a half working voltage VDD/2 so that a positive polarity signal PS is outputted to the node N1 through the first input stage 312, the first gain stage 314 and the first output stage 316. Meanwhile, the two-channel operational amplifier circuit 300 switches the second input stage 322, the second gain stage 324 and the second output stage 326 to work between the half working voltage VDD/2 and a ground voltage GND, such that a negative polarity signal NS is outputted to the node N2 through the second input stage 322, the second gain stage 324 and the second output stage 326.

Thereafter, in a second frame period FP2, the two-channel operational amplifier circuit 300 switches the second input stage 322, second gain stage 324 and the first output stage 316 to work between the working voltage VDD and the half working voltage VDD/2, such that the positive polarity signal PS is outputted to the node N2 through the second input stage 322, the second gain stage 324 and the first output stage 316. Consequently, the negative polarity signal NS and the positive polarity signal PS of the node N2 are processed by the same second input stage 322 and the same second gain stage 324 so that the problem of the voltage offset cannot arise, and are outputted from the output stage with the same polarity.

In the second frame period FP2, the two-channel operational amplifier circuit 300 also switches the first input stage 312, the first gain stage 314 and the second output stage 326 to work between the half working voltage VDD/2 and the ground voltage GND, such that the negative polarity signal NS is outputted to the node N1 through the first input stage 312, the first gain stage 314 and the second output stage 326. Consequently, the positive polarity signal PS and the negative polarity signal NS of the node N1 are processed by the same first input stage 312 and the same first gain stage 314 so that the problem of the voltage offset cannot arise, and are outputted from the output stage with the same polarity.

In addition, the first input stage 312 and the second input stage 322 can share currents because they are in the half-VDD operation mode. Similarly, the first gain stage 314 and the second gain stage 324 also can share currents because they are in the half-VDD operation mode. The first output stage 316 and the second output stage 326 also can share currents because they are in the half-VDD operation mode. Consequently, the two-channel operational amplifier circuit 300 of the invention can save the current consumption.

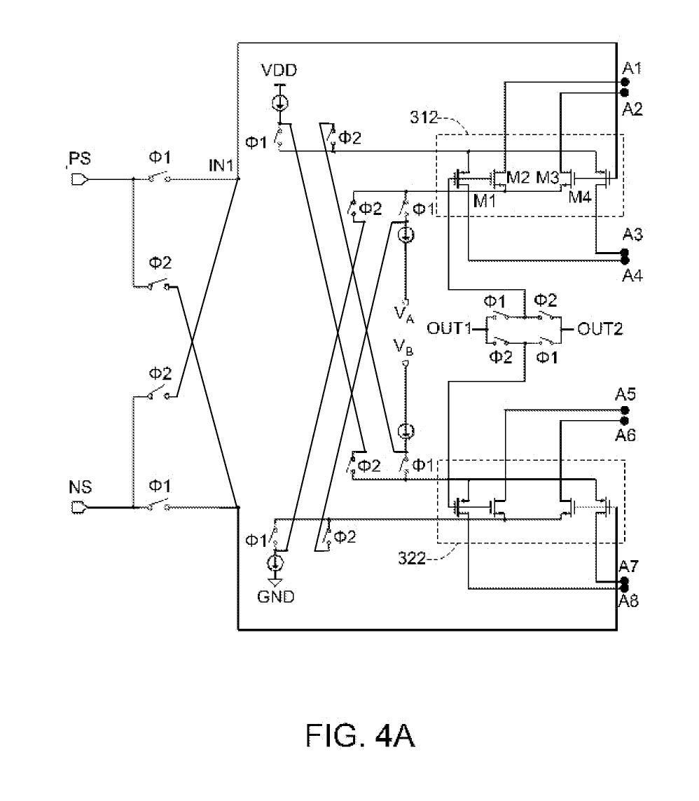

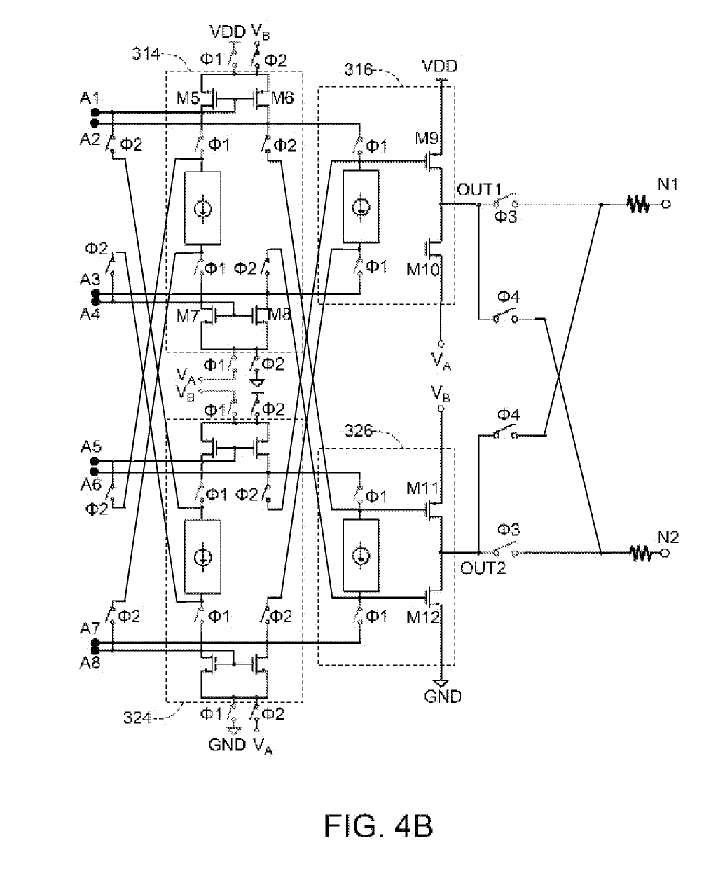

FIGS. 4A and 4B are circuit diagrams showing the two-channel operational amplifier circuit according to the preferred embodiment of the invention. Referring to FIGS. 4A and 4B, the two-channel operational amplifier circuit 300 further includes multiple first switches ψ1, multiple second switches ψ2, multiple third switches ψ3 and multiple fourth switches ψ4. The two-channel operational amplifier circuit 300 substantially switches the first input stage 312, the first gain stage 314, the first output stage 316, the second input stage 322, the second gain stage 324 and the second output stage 326 to work at working voltages through the switches ψ1 to ψ4.

In the first frame period FF1, the first switches ψ1 turn on and the second switches ψ2 turn off, so that the first input stage 312, the first gain stage 314 and the first output stage 316 work between the working voltage VDD and the half working voltage VDD/2, and the second input stage 322, the second gain stage 324 and the second output stage 326 work between the half working voltage VDD/2 and the ground voltage GND. Meanwhile, the third switches ψ3 turn on and the fourth switches ψ4 turn off, so that the first output stage 316 is coupled to the node N1, and the second output stage 326 is coupled to the node N2.

In the second frame period FP2, the first switches ψ1 turn off and the second switches ψ2 turn on, so that the second input stage 322, the second gain stage 324 and the first output stage 316 work between the working voltage VDD and the half working voltage VDD/2, and the first input stage 312, the first gain stage 314 and the second output stage 326 work between the half working voltage VDD/2 and the ground voltage GND, and the third switches ψ3 turn off and the fourth switches ψ4 turn on, so that the first output stage 316 is coupled to the node N2, and the second output stage 326 is coupled to the node N1.

The two-channel operational amplifier circuit according to the embodiment of the invention has many advantages, some of which will be described in the following.

In the two-channel operational amplifier circuit of the invention, the input stage and the gain stage of the single operational amplifier receive the positive polarity data and the negative polarity data. When the polarity conversion is performed, the input stage and the gain stage are switched to the same polarity of working voltage, and the output stage with the same polarity is switched, so that the different polarities of data of the single output node are processed by the same input stage and the same gain stage to prevent the problem of abnormal display from being caused by the voltage offset. Thus, no extra compensation mechanism is needed. In addition, the input stage, the gain stage and the output stage of the two-channel operational amplifier circuit operate in the half-VDD operation mode by switching the switches, and the current consumption may be saved.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A two-channel operational amplifier circuit, comprising:
a first operational amplifier having a first input stage, a first gain stage and a first output stage; and
a second operational amplifier having a second input stage, a second gain stage and a second output stage, wherein:
in a first frame period, the two-channel operational amplifier circuit switches the first input stage, the first gain stage and the first output stage to work between a working voltage and a half working voltage, such that a positive polarity signal is outputted to a first node through the first input stage, the first gain stage and the first output stage, and the two-channel operational amplifier circuit switches the second input stage, the second gain stage and the second output stage to work between the half working voltage and a ground voltage, such that a negative polarity signal is outputted to a second node through the second input stage, the second gain stage and the second output stage; and
in a second frame period, the two-channel operational amplifier circuit switches the second input stage, the second gain stage and the first output stage to work between the working voltage and the half working voltage, such that the positive polarity signal is outputted to the second node through the second input stage, the second gain stage and the first output stage, and the two-channel operational amplifier circuit switches the first input stage, the first gain stage and the second output stage to work between the half working voltage and the ground voltage, such that the negative polarity signal is outputted to the first node through the first input stage, the first gain stage and the second output stage.

2. The circuit according to claim 1, further comprising a plurality of first switches, a plurality of second switches, a plurality of third switches and a plurality of fourth switches, wherein:
in the first frame period, the first switches turn on and the second switches turn off, such that the first input stage, the first gain stage and the first output stage work between the working voltage and the half working voltage, and the second input stage, the second gain stage and the second output stage work between the half working voltage and the ground voltage, and the third switches turn on and the fourth switches turn off, such that the first output stage is coupled to the first node and the second output stage is coupled to the second node; and
in the second frame period, the first switches turn off and the second switches turn on, such that the second input stage, the second gain stage and the first output stage work between the working voltage and the half working voltage, and the first input stage, the first gain stage and the second output stage work between the half working voltage and the ground voltage, and the third switches turn off and the fourth switches turn on, such that the first output stage is coupled to the second node, and the second output stage is coupled to the first node.
